(19) United States
(12) Patent Application Publication
(10) Pub. No.: US 2025/0338490 A1
(43) Pub. Date: Oct. 30, 2025

(54) SEMICONDUCTOR DEVICE AND METHOD OF FABRICATING THE SAME

(71) Applicant: Fujian Jinhua Integrated Circuit Co., Ltd., Quanzhou City (CN)

(72) Inventor: Yukihiro Nagai, Quanzhou City (CN)

(73) Assignee: Fujian Jinhua Integrated Circuit Co., Ltd., Quanzhou City (CN)

(21) Appl. No.: 18/892,593

(22) Filed: Sep. 23, 2024

(30) Foreign Application Priority Data
Apr. 24, 2024 (CN) 202410502349.9

(51) Int. Cl. H10B 12/00

(52) U.S. Cl. CPC H10B 12/50; H10B 12/09; H10B 12/315; H10B 12/34

(57) ABSTRACT

The present disclosure provides a semiconductor device and a method of fabricating the same including a substrate, a first metal layer, an insulating layer, a first capacitor structure, a second metal layer, and a second capacitor structure. The substrate includes a first region and a second region. The first metal layer is disposed on the substrate within the second region. The insulating layer is disposed within the first region and the second region, overlaying the first metal layer. The first capacitor structure is disposed on the insulating layer within the first region, and partially extended into the insulating layer. The second metal layer is disposed on the insulating layer within the second region and electrically connected the first metal layer. The second capacitor structure is disposed on the second metal layer.

### BACKGROUND OF THE INVENTION

### 1. Field of the Invention

The present disclosure relates to a semiconductor device and a method of fabricating the same, and more particularly to a semiconductor device having a capacitor structure and a method of fabricating the same.

### 2. Description of the Prior Art

With the trend of miniaturization of various electronic products, the design of semiconductor devices must also meet the requirements of high integration and high density. Under the current mainstream of development trend, dynamic random access memories (DRAMs) having recessed gate structures have gradually replaced the DRAMs having only planar gate structures due to longer carrier channel length for the same semiconductor substrate so as to reduce current leakage of capacitor structures. In general, a DRAM cell with a recessed gate structure includes a transistor component and a charge storage device to receive voltage signals from bit lines and word lines. However, due to the limitations of current processing technologies, there are still many defects in currently available DRAM cells with recessed gate structures, which need to be further improved to effectively improve the performance and reliability of related memory devices.

### SUMMARY OF THE INVENTION

It is one of the primary objectives of the present disclosure to provide a semiconductor device and a method of fabricating the same, where capacitor structures with height differences are respectively arranged in two regions of the substrate, so that the capacitor structures enable to be electrically connected to different required components in an easier manner, to configure as various operations, and to achieve an optimized performance thereby.

To achieve the purpose described above, one embodiment of the present disclosure provides a semiconductor device including a substrate, a first metal layer, an insulating layer, a first capacitor structure, a second metal layer, and a second capacitor structure. The substrate includes a first region and a second region. The first metal layer is disposed on the substrate, within the second region. The insulating layer is disposed within the first region and the second region, overlaying the first metal layer. The first capacitor structure is disposed on the insulating layer within the first region, and partially extended into the insulating layer. The second metal layer is disposed on the insulating layer within the second region and electrically connected the first metal layer. The second capacitor structure is disposed on the second metal layer.

To achieve the purpose described above, one embodiment of the present disclosure provides a method of fabricating a semiconductor device, including the following steps. A substrate is provided, and which includes a first region and a second region. A first metal layer is formed on the substrate, within the second region. An insulating layer is formed within the first region and the second region, overlaying the first metal layer. A first capacitor structure is formed on the insulating layer within the first region, the first capacitor structure partially extends into the insulating layer. A second metal layer is formed on the insulating layer within the second region, the second metal layer is electrically connected the first metal layer. A second capacitor structure is formed on the second metal layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 is a schematic cross-sectional diagram illustrating a semiconductor device according to a first embodiment of the present disclosure.

FIG. 2 is a schematic cross-sectional diagram illustrating a semiconductor device according to a second embodiment of the present disclosure.

FIG. 3 to FIG. 9 are schematic diagrams illustrating a method of fabricating a semiconductor device according to a preferably embodiment of the present disclosure, wherein:

FIG. 3 is a cross-sectional view of a semiconductor device after forming a barrier material layer;

FIG. 4 is a cross-sectional view of a semiconductor device after forming a metal material layer;

FIG. 5 is a cross-sectional view of a semiconductor device after forming an insulating layer;

FIG. 6 is a cross-sectional view of a semiconductor device after forming another insulating layer;

FIG. 7 is a cross-sectional view of a semiconductor device after forming a supporting layer structure;

FIG. 8 is a cross-sectional view of a semiconductor device after forming through holes; and

FIG. 9 is a cross-sectional view of a semiconductor device after forming capacitor structures.

### DETAILED DESCRIPTION

To provide a better understanding of the presented invention, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

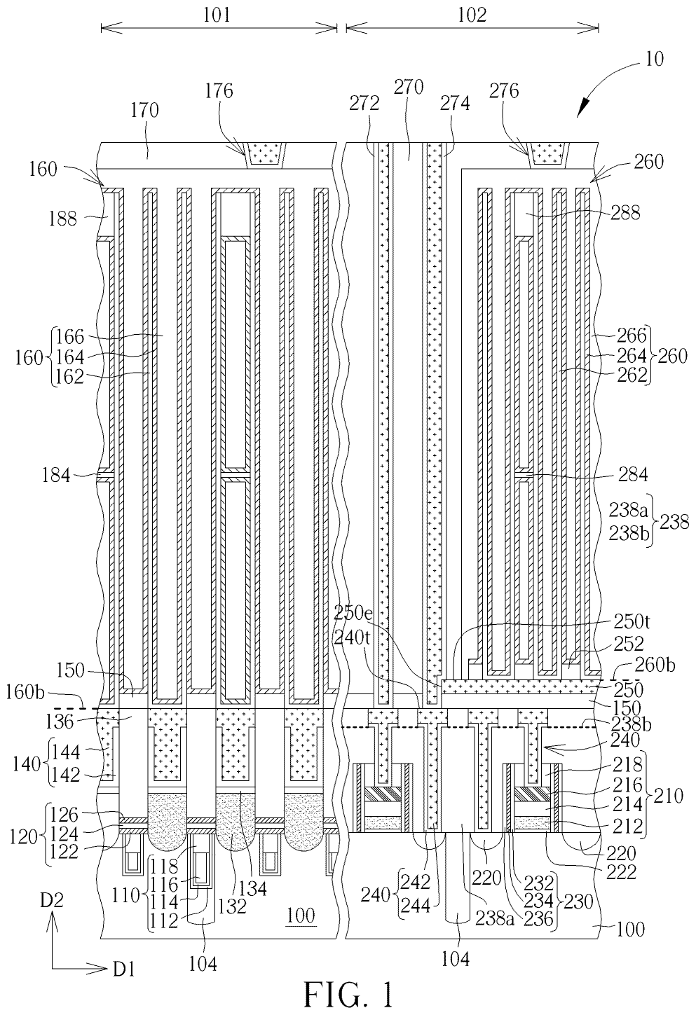

Please refer to FIG. 1, FIG. 1 is a schematic diagram illustrating a semiconductor device 10 according to the first embodiment of the present disclosure. As shown in FIG. 1, the semiconductor device 10 includes a substrate 100, a first metal layer 240, an insulating layer 150, a first capacitor structure 160, a second metal layer 250, and a second capacitor structure 260. The substrate 100 for example includes a silicon substrate, a silicon containing substrate, an epitaxial silicon substrate, a silicon-on-insulator substrate, or a substrate made of other suitable material, but not limited thereto. The substrate 100 further includes a first region 101 with a relative higher elemental integration to serve as a cell region of the semiconductor device 10, and a second region 102 with a relative lower elemental integration to serve as a peripheral region of the semiconductor device 10. In one embodiment, the first region 101 and the second region 102 may be adjacent to each other as shown in FIG. 1, but not limited thereto. Also, a plurality of shallow trench isolations 104 is disposed in the substrate 100, within the first region 101 and the second region 102, to define a plurality of active areas.

The first metal layer 240 is disposed on the substrate 100, within the second region 102. The insulating layer 150 is disposed both within the first region 101 and the second region 102, and the insulating layer 150 disposed within the second region 102 overlays the first metal layer 240. The second metal layer 250 is disposed on the insulating layer 150 within the second region 102, to electrically connect the first metal layer 240 disposed under the insulating layer 150. It is noted that, the first capacitor structure 160 is disposed on the insulating layer 150 within the first region 101, with a portion thereof penetrating through the insulating layer 150 to electrically connect a component disposed underneath. The second capacitor structure 260 is disposed on the second metal layer 250 within the second region 102, such that, the bottommost surface 160b of the first capacitor structure 160 and the bottommost surface 260b of the second capacitor structure 260 are not on the same plane. That is, through arranging the insulating layer 150 and additionally arranging the second metal layer 250 within the second region 102, the first capacitor structure 160 within the first region 101 and the second capacitor structure 260 within the second region 102 will therefore obtain a height difference therebetween. Accordingly, the first capacitor structure 160 and the second capacitor structure 260 disposed in different regions are capable of being electrically connected to different required components in an easier manner, to form various devices for performing various operations. Thus, the semiconductor device 10 of the present embodiment is allowable to achieve an optimized operation.

In one embodiment, the first capacitor structure 160 further includes a plurality of bottom electrode layers 162, a capacitor dielectric layer 164, and a top electrode layer 166, and the second capacitor structure 260 further includes a plurality of bottom electrode layers 262, a capacitor dielectric layer 264, and a top electrode layer 266. Each of the bottom electrode layers 162 and each of the bottom electrode layers 262 respectively include an U-shaped cross-section structure, with each bottom electrode layer 162 penetrating through the insulating layer 150 within the first region 101 to physically contact and to electrically connect one of a plurality of extension pads 140 underneath, and with each bottom electrode layer 262 penetrating through an insulating layer 252 disposed only within the second region 102, to physically contact and to electrically connect the second metal layer 250 within the second region 102. Also, a plurality of isolations 136 are further disposed between the extension pads 140 to isolate therefrom. The extension pads 140 and the first metal layer 240 within the second region 102 preferably include the same conductive material. For example, the extension pads 140 and the first metal layer 240 may respectively include a barrier layer 142, 242 and a metal layer 144, 244 stacked in sequence, with the barrier layer 142, 242 for example including a conductive barrier material like titanium and/or titanium nitride, tantalum and/or tantalum nitride, and with the metal layer 144, 244 for example including a low-resistance metal material like copper, aluminum or tungsten, but not limited thereto. It is noted that the second capacitor structure 260 is disposed on the second metal layer 250 and the insulating layer 150 within the second region 102, so that, the bottom surface (namely the bottommost surface 260b of the second capacitor structure 260) of the bottom electrode layers 262 of the second capacitor structure 260 will be higher than the bottom surface (namely the bottommost surface 160b of the first capacitor structure 160) of the bottom electrode layers 162 of the first capacitor structure 160, as shown in FIG. 1.

Precisely speaking, the semiconductor device 10 further includes a plurality of first plugs 132 and a plurality of first gate structures 110 disposed within the first region 101. The first plugs 132 are disposed on the substrate 100, with each of the first plugs 132 being disposed under each of the extension pads 140, to physically contact the active areas of the substrate 100. A metal silicide layer 134 may be further disposed between each first plug 132 and each extension pad 140, and any adjacent ones of the first plugs 132 are also isolated from each other by the isolations 136. In one embodiment, the metal silicide layer 134 for example includes a metal silicide material like cobalt silicide (CoSi₂), titanium silicide (TiSi₂) or nickel silicide (Ni₂Si), and the first plugs 132 for example include an epitaxial material like silicon (Si), silicon phosphorus (SiP), silicon germanium (SiGe) or germanium (Ge), but not limited thereto. Accordingly, the first plugs 132 and the extension pads 140 will therefore serve as storage node contacts (SNCs) and storage node pads (SN pads) of the semiconductor device 10 respectively, to electrically connect the first capacitor structure 160.

The first gate structures 110 are disposed in the substrate 100, and each includes an interface layer 112, a gate dielectric layer 114, a gate layer 116 and a capping layer 118 stacked in sequence, with the top surface of the capping layer 118 being coplanar with the top surface of the substrate 100. Then, the first gate structures 110 may be covered by a dielectric layer 120 disposed on the substrate 100 within the first region 101, so as to function like buried gates. In one embodiment, the dielectric layer 120 for example includes an oxide layer 122, a nitride layer 124 and an oxide layer 126 stacked in sequence, to obtain an oxide-nitride-oxide (ONO) structure, but not limited thereto. In this way, the first gate structures 110 may therefore serve as buried word lines (BWLs) of the semiconductor device 10, with each of the first gate structures 110 and a doped region (not shown in the drawings) also disposed in the substrate 100 within the first region 101 together forming a transistor component (not shown in the drawings). With these arrangements, each first capacitor 160 and the transistor component both within the first region 101 will together form a smallest memory cell of a memory device, for receiving voltage signals from bit line (BL, not shown in the drawings) and the buried word lines. Furthermore, the smallest memory cell of the memory device may be further electrically connected to any requested component through a connection structure 176 disposed in an inter-metal dielectric layer 170 overlaying the first capacitor structure 160, so that, the semiconductor device 10 of the present embodiment is allowable to be configured as a dynamic random access memory (DRAM) device for achieving better operation and performance.

On the other hand, further in view of FIG. 1, the semiconductor device 10 further includes a plurality of second gate structures 210, a second plug 272 and a metal interconnection structure 274, within the second region 102. The second gate structures 210 are respectively disposed on a gate dielectric layer 222, and each includes a semiconductor layer 212, a barrier layer 214, a metal layer 216 and a capping layer 218 stacked in sequence. In one embodiment, the gate dielectric layer 222 for example includes an insulating material like silicon oxide, the semiconductor layer 212 for example includes a semiconductor material like doped polysilicon or doped amorphous silicon, the barrier layer 214 for example includes a conductive barrier material like titanium and/or titanium nitride, or tantalum and/or tantalum nitride, the metal layer 216 for example includes a low-resistance metal material like copper, aluminum, or tungsten, and the capping layer 218 for example includes an insulating material like silicon oxide, silicon nitride or silicon oxynitride, but not limited thereto. Also, a spacer structure 230 is further disposed on a sidewall of each second gate structure 210, and which includes a spacer 232, a spacer 234, and a spacer 236 stacked in sequence. In one embodiment, the spacer 232 and the spacer 236 for example include the same insulating material, like silicon nitride, or silicon carbonitride, and the spacer 234 for example includes an insulating material being different from that of the spacer 232 and the spacer 236, like silicon oxide or silicon oxynitride, but not limited thereto. Furthermore, doped regions 220 are further disposed in the substrate 100, at two sides of each second gate structure 210, with each second gate structure 210 and the doped regions 220 adjacent thereto together forming a transistor component (not shown in the drawings) within the second region 102.

It is noted that, the first metal layer 240 is disposed in an interlayer dielectric layer 238 overlaying the second gate structures 210, and which may further include a trench portion extending in the horizontal direction D1 and a via portion extending in the vertical direction D2. The via portion of each first metal layer 240 physically contacts the metal layer 216 of one corresponding second gate structure 210, or one corresponding doped region 220 at a side of the second gate structures 210. The insulating layer 150 overlays the trench position of each first metal layer 240.

The second plug 272 and the metal interconnection structures 274 are disposed in an inter-metal dielectric layer 270 overlaying the insulating layer 150 and the second capacitor structure 260, with the second plug 272 penetrating through the insulating layer 150 to physically contact the trench portion of a corresponding one of the first metal layers 240, and with the metal interconnection structure 274 physically contacting the second metal layer 250 and the trench portion of another corresponding one of the first metal layers 240. That is, the metal interconnection structure 274 will directly contact the top surface 240t of the another corresponding one of the first metal layers 240, and the top surface 250t and the sidewall 250e of the second metal layer 250 at the same time, to electrically connect the transistor component within the second region 102 to the second capacitor structure 260. With these arrangements, the second capacitor structure 260 and the transistor component within the second region 102 will also form a smallest memory cell of another memory device, with the smallest memory cell of the another memory device being electrically connected to any requested component through a connection structure 276 in the inter-metal dielectric layer 270, for achieving better operation and performance. In one embodiment, the second plug 272 and the metal interconnection structure 274 respectively include a barrier layer (not shown in the drawings, for example including a conductive barrier material like titanium and/or titanium nitride, or tantalum and/or tantalum nitride) and a metal layer (not shown in the drawings, for example including a low-resistance metal material like copper, aluminum, or tungsten), but not limited thereto.

According to the semiconductor device 10 of the present embodiment, while arranging the insulating layer 150 both within the first region 101 and the second region 102, and further arranging the second metal layer 250 within the second region 102, the first capacitor structure 160 within the first region 101 and the second capacitor structure 260 within the second region 102 will be respectively disposed on the insulating layer 150 and on the second metal layer 250, thereby being not coplanar with each other. Also, the insulating layer 252 only within the second region 102 is further disposed on the second metal layer 250. Then the first capacitor structure 160 within the first region 101 partially penetrates through the insulating layer 150, to electrically connect the transistor component within the first region 101 through the storage node pads and the storage node contacts, and the second capacitor structure 260 within the second region 102 partially penetrates through the insulating layer 252, to electrically connect the transistor component disposed within the second region 102 through the second metal layer 250 and the first metal layer 240. With these arrangements, the first capacitor structure 160 and the second capacitor structure 260 disposed within different regions will therefore have a height differences therebetween, due to the second metal layer 250 being additionally arranged within the second region 102. That is, the first capacitor structure 160 and the second capacitor structure 260 disposed within different regions enables to be electrically connected to different required components in an easier manner through various connection structures 176, 276, to be configured as various devices for achieving different operations. Then, the semiconductor device 10 of the present embodiment will therefore gain an optimized performance thereby.

Those of ordinary skill in the art should easily realize the semiconductor device in the present disclosure are not limited to the aforementioned embodiment, and which may include other examples or varieties. The following description will detail the different embodiments of the semiconductor device in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

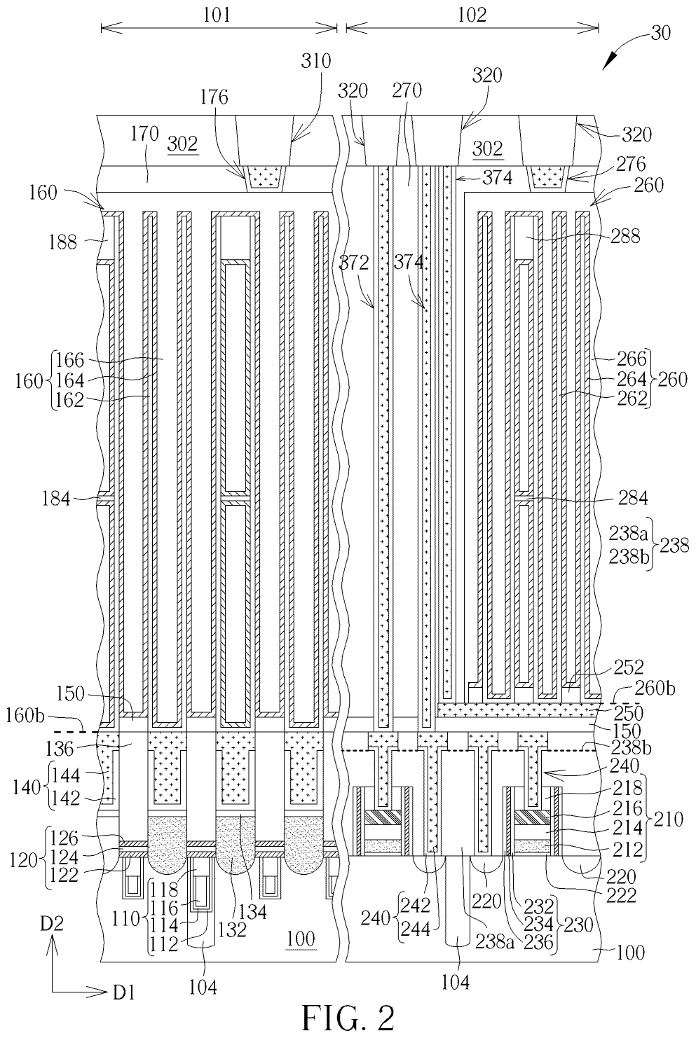

Please refer to FIG. 2, which is a schematic cross-sectional view of a semiconductor device 30 according to the second embodiment of the present disclosure. The structure of the semiconductor device 30 in the present embodiment is substantially the same as that of the semiconductor device 10 of the aforementioned embodiment, and all the similarities will not be redundantly described hereinafter. The difference between the semiconductor device 30 and the semiconductor device 10 is mainly in that the semiconductor device 30 further includes a plurality of metal interconnection layers 320 and a plurality of third plugs 374 disposed within the second region 102, wherein the third plugs 374 physically contacts a corresponding one of the first metal layers 240 and the second metal layer 250.

Precisely speaking, according to the semiconductor device 30 of the present embodiment, the second plug 372 and the third plugs 374 are simultaneously disposed in the inter-metal dielectric layer 270, to physically contact the trench portion of the corresponding one of the first metal layers 240 and the second metal layer 250 respectively. Furthermore, an inter-metal dielectric layer 302, as well as metal interconnection layers 310, 320 in the inter-metal dielectric layer 302, are additionally disposed on the inter-metal dielectric layers 170, 270, with the metal interconnection layer 310 disposed within the first region 101 physically contacting the connection structure 176 to electrically connect to the smallest memory cell of the memory device in the first region 101, and with the metal interconnection layers 320 disposed within the second region 102 physically contacting the connection structure 276, the second plugs 273 and the third plugs 374 respectively.

It is noted that, at least one metal interconnection layer 320 physically contacts at least two third plugs 374 at the same time, with the bottom of one of the at least two third plugs 374 physically contacting the second metal layer 250, and with the bottom of another one of the at least two third plugs 374 partially contacting the trench portion of the corresponding one of the first metal layers 240. Also, the sidewall of the another one of the at least two third plugs 374 may optionally contact (not shown in the drawings) or not contact (as shown in FIG. 2) to the sidewall of the second metal layer 250. Accordingly, due to the arrangement of the third plugs 374 and the metal interconnection layers 320, the second metal layer 250 of the present embodiment is still electrically connected to the first metal layer 240, and the metal interconnection layers 320 within the second region 102 enable to be further connected to the smallest memory cell of the memory device within the second region 102 through the connection structure 276.

With these arrangements, the first capacitor structure 160 and the second capacitor structure 260 disposed within different regions of the semiconductor device 30 will still have a height differences therebetween, due to the arrangements of the insulating layer 150 and the second metal layer 250. Then, the first capacitor structure 160 and the second capacitor structure 260 disposed within different regions are also capable of being easily connected to the different required components via different connection structures 176, 276, to be configured as various devices for achieving different operations. Thus, the semiconductor device 30 of the present embodiment will also gain an optimized performance thereby.

In order to make those having ordinary skills in the art easily understand the semiconductor device 10 according to the present disclosure, a fabricating method of the semiconductor device 10, 30 according to the present disclosure will be further described as follows.

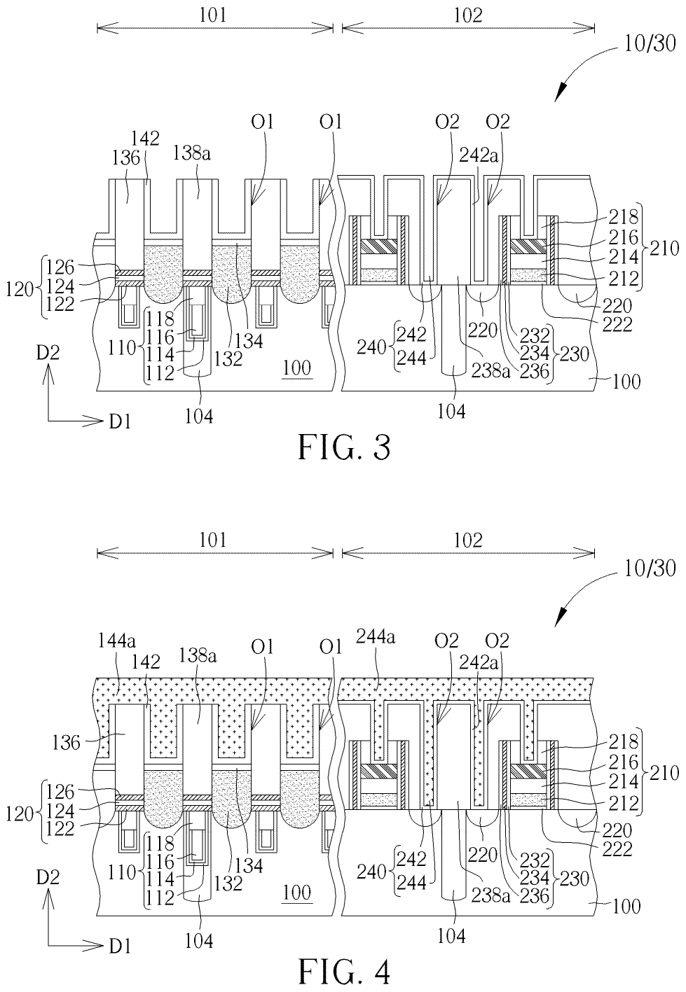

Please refer FIG. 3 to FIG. 9, which are schematic diagrams illustrating a method of fabricating the semiconductor device 10, 30 according to a preferably embodiment of the present disclosure. Firstly, as shown in FIG. 3, the substrate 100 is provided, and the shallow trench isolations 104 are formed in the substrate 100, to define the active areas both within in the first region 101 and within the second region 102. In one embodiment, the formation of the shallow trench isolations 104 is carried by firstly forming a plurality of shallow trenches (not shown in the drawings) in the substrate 100 via an etching process, followed by filling at least one insulating material (such as including silicon oxide or silicon nitride) in the shallow trenches, to form the shallow trench isolations 104 having a top surface being coplanar with the top surface of the substrate 100, but not limited thereto.

Next, the first gate structures 110 are formed in the substrate 100, within the first region 101. In one embodiment, the formation of the first gate structures 110 includes but not limited to the following steps. Firstly, a plurality of trenches (not shown in the drawings) is formed in the substrate 100, interleaving plural active areas and the shallow trench isolations 104 at the same time, and the interface layer 112 covering entire surfaces of each trench, the gate dielectric layer 114 covering surfaces of a bottom portion of each trench, the gate layer 116 filled in the bottom portion of each trench, and the capping layer 118 filled in a top portion of each trench are sequentially formed in each trench. Then, the dielectric layer 120 and the gate dielectric layer 222 are formed on the substrate 100, respectively within the first region 101 and the within the second region 102. In one embodiment, the formations of the dielectric layer 120 and the gate dielectric layer 222 include but not limited to the following steps. Firstly, a first oxide material layer (not shown in the drawings), a nitride material layer (not shown in the drawings), and a second oxide material layer (not shown in the drawings) stacked in sequence are formed on the substrate 100 within the first region 101 and the second region 102, and the second oxide material layer and the nitride material layer formed within the second region 102 are then removed. Accordingly, the first oxide material layer remained in the second region 102 becomes the gate dielectric layer 222, and the second oxide material layer, the nitride material layer and the first oxide material layer in the first region 101 together form the dielectric layer 120. Alternately, in another embodiment, the second oxide material layer, the nitride material layer and the first oxide material layer within the second region 102 may also be completely removed and the gate dielectric layer 222 is additionally formed within the second region 102 hereinafter. In other words, the fabrication of the gate dielectric layer 222 within the second region 102 may be optionally integrated into the fabrication of the dielectric layer 120 within the first region 101, such that, the gate dielectric layer 222 and the oxide layer 122 may preferably include the same material, but not limited thereto.

Then, the second gate structures 210 and the spacer structures 230 are formed on the substrate 100 within the second region 102, and the doped regions 220 are next formed at two sides of each second gate structure 210 and the spacer structure 230, in the substrate 100. In one embodiment, the formation of the second gate structure 210 includes but not limited to the following steps. Firstly, a semiconductor material layer (not shown in the drawings, for example including a semiconductor material like polysilicon or doped amorphous silicon), a barrier material layer (not shown in the drawings, for example including a conductive barrier material like titanium and/or titanium nitride, tantalum and/or tantalum nitride), a metal material layer (not shown in the drawings, for example including a low-resistance metal material like copper, aluminum, or tungsten), and a capping material layer (not shown in the drawings, for example including an insulating material like silicon oxide, silicon nitride or silicon oxynitride) are sequentially formed within the second region 102, followed by performing a patterning process on the capping material layer, the metal material layer, the barrier material layer, and the semiconductor material layer, to form the second gate structures 210. Then, the spacer structure 230 is formed on the sidewall of each second gate structure 210. In one embodiment, the formation of the spacer structure 230 is carried out by sequentially forming a first spacer material layer (not shown in the drawings, for example including silicon nitride or silicon carbonitride), a second spacer material layer (not shown in the drawings, for example including silicon oxide or silicon oxynitride), and a third spacer material layer (not shown in the drawings, for example including silicon nitride or silicon carbonitride) entirely covering the second gate structures 210, and next performing an etching back process on the third spacer material layer, the second spacer material layer and the first spacer material layer, to form the spacer 232, the spacer 234 and the spacer 236 stacked in sequence on the sidewall of each second gate structure 210, thereby forming the spacer structure 230. It is noted that, in one preferably embodiment, the formation of the second gate structures 210 within the second region 102 may also be integrated into the fabrication of bit line structures (not shown in the drawings) within the first region 101, so that, the bit line structures and the second gate structures 210 will therefore include the same stacked structure and the same materials, but not limited thereto.

Following these, a deposition process is performed, to simultaneously form an insulating material layer 138a within the first region 101 and an insulating material layer 238a within the second region 102, and the insulating material layer 138a within the first region 101 and the insulating material layer 238a within the second region 102 are both partially removed through a mask layer (not shown in the drawings), to form a plurality of openings O1, O2. Each of the openings O1 is formed within the first region 101, to individually expose a portion of the substrate 100, and each of the openings O2 is formed within the second region 102, to individually expose one doped region 220 or the metal layer 216 of one second gate structures 210. After completely removing the mask layer, an epitaxial growth process is performed through another mask layer (not shown in the drawings), to form the first plugs 132 in the openings O1 respectively within the first region 101, and then, a metal silicide process is performed, to form the metal silicide layer 134 on each first plug 132. Then, the first plugs 132 formed accordingly enable to be used as storage node contacts of the semiconductor device 10, 30. After completely removing the another mask layer, a deposition process is further performed, to form a barrier material layer (not shown in the drawings, for example including a conductive barrier material like titanium and/or titanium nitride, tantalum and/or tantalum nitride) both within the first region 101 and the second region 102, with the barrier material layer being partially formed within the openings O1, O2, and partially formed outside the openings O1, O2, as shown in FIG. 3. Subsequently, an etching back process is performed on the barrier material layer within the first region 101, to form the barrier layer 142 within the first region 101, and the barrier material layer remained in the second region 102 forms the barrier material layer 242a.

As shown in FIG. 4, another deposition process is performed, to simultaneously form a metal material layer 144a within the first region 101 and a metal material layer 244a within the second region 102, with the metal material layers 144a, 244a for example including a low-resistant metal material like copper, aluminum, or tungsten, to fill in the rest space of the openings O1, O2 and to further overlay the top surfaces of the insulating material layer 138a within the first region 101 and the insulating material layer 238a within the second region 102.

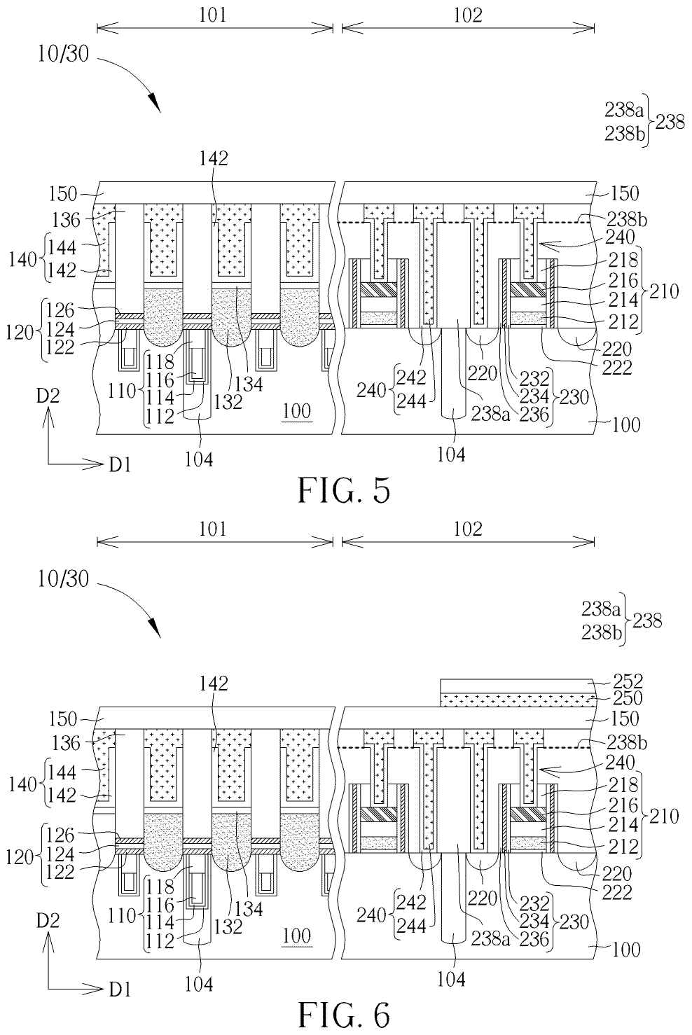

As shown in FIG. 5, a patterning process is performed on the metal material layers 144a, 244a and the barrier material layer 242a, to form the extension pads 140 within the first region 101 and the first metal layers 240 with in the second region 102, respectively. Next, the insulating material layer 138a within the first region 101 is completely removed, and a deposition process and an etching back process are then performed within the first region 101, to form the isolations 136 between the extension pads 140 and the first plugs 132. The isolations 136 each includes a top surface coplanar with the extension pads 140, and has a suitable insulating material such as silicon nitride, silicon oxynitride, or silicon carbonitride. Accordingly, the extension pads 140 will therefore serve as storage node pads of the semiconductor device 10, 30, and each first metal layer 240 further includes the via portion physically contacting the corresponding metal layer 216 or the corresponding doped region 220, and the trench portion extending in the horizontal direction D1. In addition, another deposition process and another etching back process are performed within the second region 102, to fill an insulating material 238b in the space between the first metal layers 240, such that, the insulating material 238b and the aforementioned insulating material layer 238a will together form the interlayer dielectric layer 238 being coplanar with the top surface of the first metal layers 240. After that, a deposition process is further performed, to form the insulating layer 150, for example including an insulating material like silicon oxide, silicon nitride, silicon oxynitride, or silicon carbonitride, both within the first region 101 and within the second region 102, overlaying the extension pads 140 and the insulating spacers 136 within the first region 101, as well as the first metal layers 240 and the interlayer dielectric layer 238 within the second region 102.

As shown in FIG. 6, at least one deposition process and at least one patterning process are performed, to form the second metal layers 250 and the insulating layer 252 within the second region 102. The second metal layers 250 and the insulating layer 252 overlay a portion of the first metal layers 240, with a sidewall of the second metal layers 250 being vertically aligned with the sidewall of the insulating layer 252, but not limited thereto. In one embodiment, the second metal layers 250 for example include a low-resistance metal material like copper, aluminum, or tungsten, but not limited thereto.

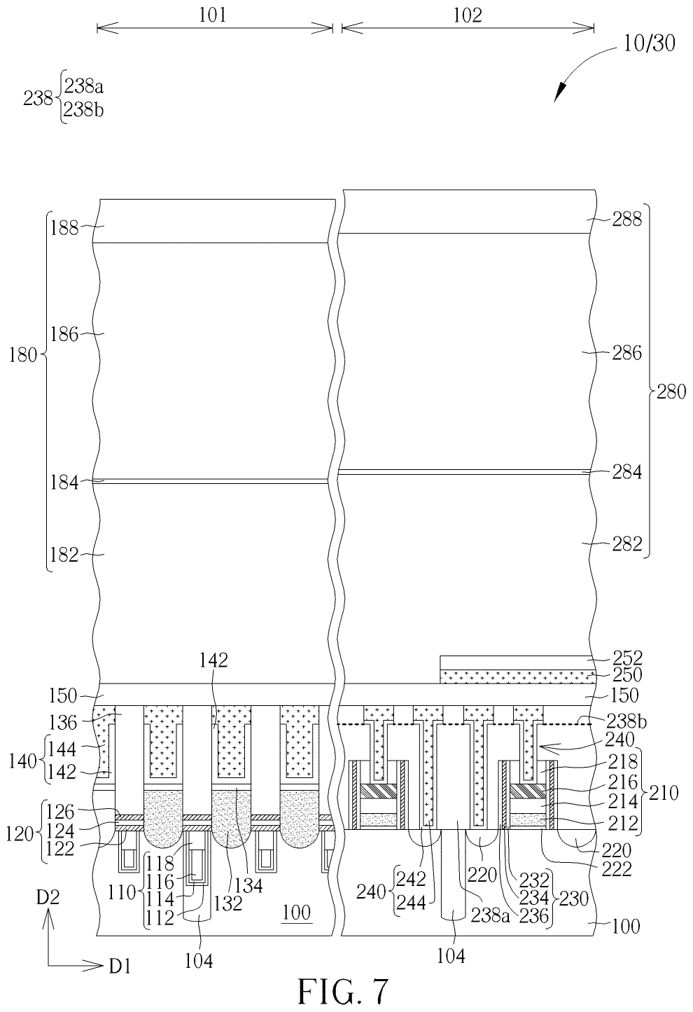

As shown in FIG. 7, a supporting layer structure 180 within the first region 101 and a supporting layer structure 280 within the second region 102 are simultaneously formed on the substrate 100, with each including a first supporting material layer 182/282 (for example including silicon oxide), a second supporting material layer 184/284 (for example including silicon nitride or silicon carbonitride), a third supporting material layer 186/286 (for example including silicon oxide), and a fourth supporting material layer 188/288 (for example including silicon nitride or silicon carbonitride) stacked in sequence from bottom to top, but not limited thereto. In one embodiment, each of the first supporting material layers 182, 282 and the third supporting material layers 186, 286 preferably includes a relative greater thickness, for example being about 5-10 times greater than that of each of the second supporting material layers 184, 284 and the fourth supporting material layers 188, 288. Also, the thickness of each fourth supporting material layer 188, 288 is preferably greater than that of each second supporting material layer 184, 284, but not limited thereto. Accordingly, the supporting layer structures 180, 280 may obtain an overall thickness in about 1600-2000 angstroms, but not limited thereto.

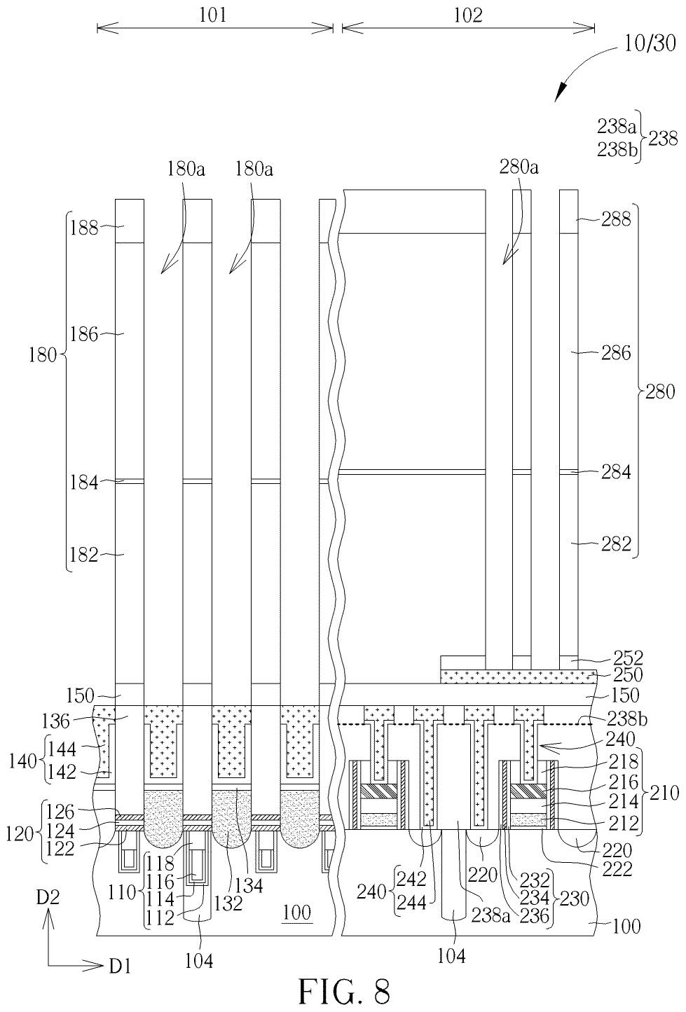

As shown in FIG. 8, a plurality of through holes 180a is formed in the supporting layer structure 180, and a plurality of through holes 280a is formed in the supporting layer structure 280, with each through hole 180a/280a penetrating through the fourth supporting material layer 188/288, the third supporting material layer 186/286, the second supporting material layer 184/284, and the first supporting material layer 182/282. It is noted that, each through hole 180a further penetrates through the insulating layer 150 within the first region 101, being aligned with and physically contacting to each extension pad 140 underneath, and each through hole 280a further penetrates through the insulating layer 252 only formed within the second region 102, to physically contact the second metal layer 250 underneath.

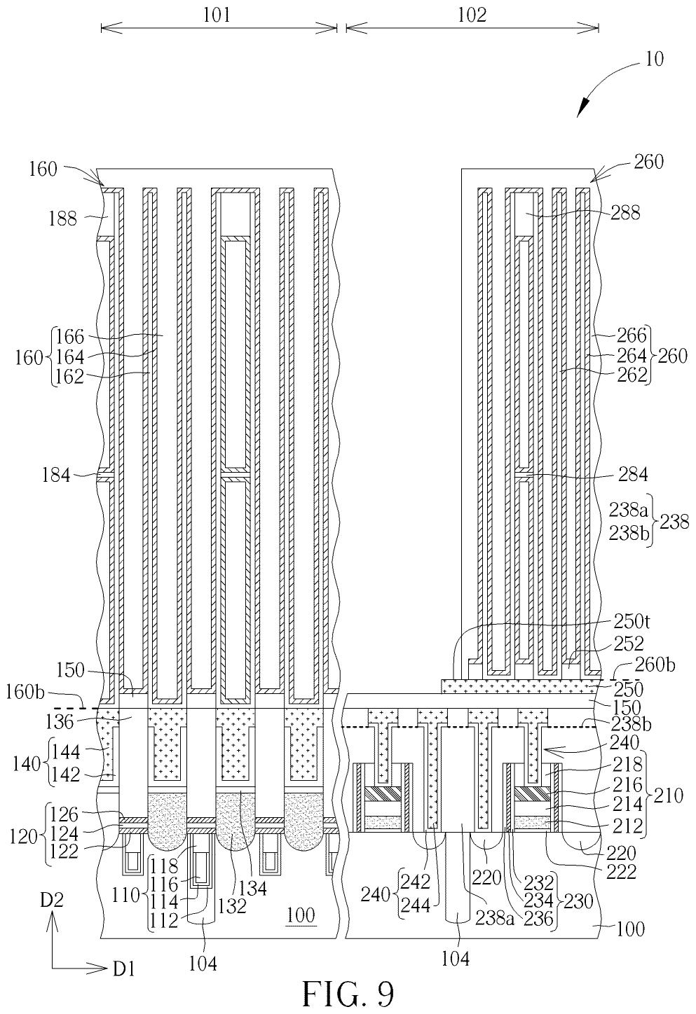

As shown in FIG. 9, the bottom electrode layers 162 are formed in the through holes 180a within the first region 101 respectively, and the bottom electrode layers 262 are formed in the through holes 280a within the second region 102 respectively, with each bottom electrode layer 162/262 obtaining a U-shaped cross-section structure. Next, at least one etching process is performed through a mask layer (not shown in the drawings), to completely remove the third supporting material layers 186, 286 and the first supporting material layers 182, 282, and to partially remove the fourth supporting material layers 188, 288 and the second supporting material layers 184, 284. Then, after completely removing the mask layer, at least one deposition process is performed, to simultaneously form the capacitor dielectric layer 164 within the first region 101 and the capacitor dielectric layer 264 within the second region 102, and to simultaneously formed the top electrode layer 166 within the first region 101 and the top electrode layer 266 within the second region 102. The capacitor dielectric layers 164, 264 respectively overlay the bottom electrode layers 162, 262, and the top electrode layers 166, 266 fill in the rest space between the bottom electrode layers 162, 262.

Through these performances, the bottom electrode layers 162, the capacitor dielectric layer 164, and the top electrode layer 166 formed within the first region 101 together form the first capacitor structure 160, and the fourth supporting material layer 188 and the second supporting material layer 182 together form a supporting structure for supporting the first capacitor structure 160. On the other hand, the bottom electrode layers 262, the capacitor dielectric layer 264, and the top electrode layer 266 formed within the second region 102 together form the second capacitor structure 260, and the fourth supporting material layer 288 and the second supporting material layer 282 together form a supporting structure for supporting the second capacitor structure 260. The bottom electrode layers 162 of the first capacitor structure 160 penetrate through the insulating layer 150 within the first region 101, thereby landing on the extension pads 140 respectively, and the bottom electrode layers 262 of the second capacitor structure 260 penetrate through the insulating layer 252 within the second region 102, thereby landing on the first metal layers 240 respectively. That is, the first capacitor structure 160 and the second capacitor structure 260 are not formed on the same plane. In this way, due to the height difference between the first capacitor structure 160 and the second capacitor structure 260 disposed in different regions, connection structures for individually connecting to the first capacitor structure 160 and the second capacitor structure 260 may be easily fabricated in the subsequent processes, to electrically connect the first capacitor structure 160 and the second capacitor structure 260 to various components in a more easier manner, to form different devices to perform different operations.

For example, in the following processes, the inter-metal dielectric layer 170 may be formed within the first region 101, and the inter-metal dielectric layer 270 may be formed within the second region 102 in the subsequent process, overlaying the first capacitor structure 160 and the second capacitor structure 260 respectively. Then, the second plug 272, the metal interconnection structures 274 and the connection structures 176, 276 as shown in FIG. 1 are optionally formed through the same process or different processes. Alternately, the second plug 372 and the third plugs 374 as shown in FIG. 2 may be firstly formed in the inter-metal dielectric layer 270, and the metal interconnection layers 320 are then formed with one of the metal interconnection layers 320 physically contacting at least two of the third plugs 374 at the same time. The bottom of one of the at least two third plugs 374 physically contacts the second metal layer 250, and the bottom of another one of the at least two third plugs 374 contacts the first metal layer 240, with the sidewall of the another one of the at least two third plugs 374 optionally contacting or not contacting the sidewall of the second metal layer 250, but not limited thereto.

According to the fabricating method of the present embodiment, the insulating layer is formed on the substrate entirely overlaying the first region and the second region, and the second metal layer is then formed within the second region, so as to result in the height difference between the first capacitor structure within the first region and the second capacitor structure within the second region by integrating the fabricating process of the first capacitor structure and the second capacitor structure in two different regions. In this way, the first capacitor structure and the second capacitor structure disposed in different regions are capable of being electrically connected to the connection structures or the interconnection structures in an easier manner, to form different devices to perform different operations. Thus, the fabricating method of the semiconductor device of the present embodiments will therefore achieve more optimized operation performance, under a simplified process flow.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate, comprising a first region and a second region;
a first metal layer, disposed on the substrate, within the second region;
an insulating layer, disposed within the first region and the second region, overlaying the first metal layer;
a first capacitor structure, disposed on the insulating layer within the first region, and partially extended into the insulating layer;
a second metal layer, disposed on the insulating layer within the second region and electrically connected the first metal layer; and
a second capacitor structure, disposed on the second metal layer.

2. The semiconductor device according to claim 1, wherein a bottommost surface of the second capacitor structure and a bottommost surface of the first capacitor structure are not coplanar.

3. The semiconductor device according to claim 1, wherein the second capacitor structure and the first capacitor structure respectively comprise a bottom electrode layer, a capacitor dielectric layer, and a top electrode layer, and the bottom electrode layer of the second capacitor structure physically contacts the second metal layer.

4. The semiconductor device according to claim 3, wherein a bottom surface of the bottom electrode layer of the second capacitor structure is higher than a bottom surface of the bottom electrode layer of the first capacitor structure.

5. The semiconductor device according to claim 1, further comprising:
an extension pad, disposed within the first region, under the insulating layer, the extension pad and the first metal layer comprising a same conductive material, wherein the first capacitor structure is disposed on the extension pad.

6. The semiconductor device according to claim 5, further comprising:
a first gate structure, disposed in the substrate within the first region, the first gate structure and the first capacitor structure being configured as a memory cell.

7. The semiconductor device according to claim 1, further comprising:
a first gate structure, disposed in the substrate within the first region;
a first plug, disposed within the first region and physically contacting the substrate; and
a second gate structure, disposed on the substrate within the second region, wherein the first metal layer further comprising a via portion physically contacting a doped region disposed at one side of the second gate structure.

8. The semiconductor device according to claim 7, further comprising:
a plurality of second plugs disposed within the second region, physically contacting the first metal layer and the second metal layer respectively; and
a metal interconnection layer disposed on the second plugs, physically contacting the second plugs.

9. The semiconductor device according to claim 7, further comprising:
a metal interconnection structure physically contacting a top surface of the first metal layer, a top surface and a sidewall of the second metal layer.

10. A method of fabricating a semiconductor device, comprising:
providing a substrate comprising a first region and a second region;
forming a first metal layer on the substrate, within the second region;
forming an insulating layer within the first region and the second region, overlaying the first metal layer;
forming a first capacitor structure on the insulating layer within the first region, the first capacitor structure partially extended into the insulating layer;
forming a second metal layer on the insulating layer within the second region, the second metal layer being electrically connected the first metal layer; and
forming a second capacitor structure on the second metal layer.

11. The method of fabricating the semiconductor device according to claim 10, further comprising:
forming a first gate structure on the substrate, within the first region;
forming a first plug on the substrate, physically contacting the substrate; and
forming a second gate structure on the substrate, within the second region, wherein the first metal layer further comprises a via portion physically contacting a doped region disposed at one side of the second gate structure.

12. The method of fabricating the semiconductor device according to claim 11, further comprising:
forming an extension pad on the first plug, wherein the extension pad and the first metal layer are simultaneously formed and comprises a same conductive material, and the first capacitor structure is formed on the extension pad.

13. The method of fabricating the semiconductor device according to claim 12, wherein the first gate structure and the first capacitor structure together form a memory cell.

14. The method of fabricating the semiconductor device according to claim 11, further comprising:
forming a plurality of second plugs within the second region, physically contacting the first metal layer and the second layer respectively; and
forming a metal interconnection layer on the second plugs, physically contacting the second plugs.

15. The method of fabricating the semiconductor device according to claim 11, further comprising:
forming a metal interconnection structure on the first metal layer and the second metal layer, wherein the metal interconnection structure physically contacts a top surface of the first metal layer, and a top surface and a sidewall of the second metal layer.

16. The method of fabricating the semiconductor device according to claim 11, wherein a bottommost surface of the second capacitor structure is not coplanar with a bottommost surface of the first capacitor structure.

17. The method of fabricating the semiconductor device according to claim 11, wherein the second capacitor structure and the first capacitor structure respectively comprise a bottom electrode layer, a capacitor dielectric layer, and a top electrode layer, and the bottom electrode layer of the second capacitor structure physically contacts the second metal layer.

18. The method of fabricating the semiconductor device according to claim 17, wherein a bottom surface of the bottom electrode layer of the second capacitor structure is higher than a bottom surface of the bottom electrode layer of the first capacitor structure.
